(19) United States
(12) Patent Application Publication
(10) Pub. No.: US 2013/0207226 A1
(43) Pub. Date: Aug. 15, 2013

(54) RECESSED DEVICE REGION IN EPITAXIAL INSULATING LAYER

(71) Applicants: Thomas N. Adam, Slingerlands, NY (US); Kangguo Cheng, Schenectady, NY (US); Ali Khakifirooz, Mountain View, CA (US); Alexander Reznicek, Troy, NY (US); Raghavasimhan Sreenivasan, Schenectady, NY (US)

(72) Inventors: Thomas N. Adam, Slingerlands, NY (US); Kangguo Cheng, Schenectady, NY (US); Ali Khakifirooz, Mountain View, CA (US); Alexander Reznicek, Troy, NY (US); Raghavasimhan Sreenivasan, Schenectady, NY (US)

(73) Assignee: INTERNATIONAL BUSINESS MACHINES CORPORATION, Armonk, NY (US)

(21) Appl. No.: 13/371,665

(22) Filed: Feb. 13, 2012

(51) Int. Cl. H01L 29/06; H01L 21/762

(52) U.S. Cl. 257/507; 438/413; 257/E29.022; 257/E21.561

(57) ABSTRACT

A method for isolating semiconductor devices is described wherein an epitaxial insulating layer is grown on a semiconductor substrate. The epitaxial insulating layer is etched to form a recessed region within the layer. An epitaxial semiconductor material is grown with the recessed region to form a semiconductor device region separated from other potential device regions by non-recessed portions of the epitaxial insulating layer.

### FIELD OF THE INVENTION

This disclosure relates generally to semiconductor devices and more specifically to isolating semiconductor devices from each other.

### BACKGROUND OF THE INVENTION

The fabrication of semiconductor devices involves forming electronic components in and on semiconductor substrates, such as silicon wafers. These electronic components may include one or more conductive layers, one or more insulation layers, and doped regions formed by implanting various dopants into portions of a semiconductor substrate to achieve specific electrical properties. Semiconductor devices include transistors, resistors, capacitors, and the like, with intermediate and overlying metallization patterns at varying levels, separated by dielectric materials, which interconnect the semiconductor devices to form integrated circuits.

To electrically isolate semiconductor devices from each other, various isolation structures, such as trench isolation structures, have been used. Viewing the vertical direction as into the depth, or thickness, of a given substrate and the horizontal direction as being parallel to a top surface of the substrate, a trench isolation structure is vertically oriented to provide insulating separation between semiconductor devices at different horizontal locations. Traditionally, a semiconductor surface is etched to form separate device regions, and resulting trenches in between the separate device regions are filled with dielectric material to form the trench isolation structures.

A semiconductor substrate may also employ semiconductor on insulator (SOI) substrate arrangements, such as silicon on insulator substrates. In a semiconductor on insulator arrangement, a semiconductor layer can be formed above an insulation layer which has been formed on the semiconductor substrate. Devices can be formed in the top semiconductor layer. The insulating layer provides isolation from the substrate, thereby decreasing capacitances for both devices and electrical connections. The top semiconductor layer can be etched, as described above, to provide trench isolation between device regions.

Growing an epitaxial insulating layer on a semiconductor substrate is known. Oxides such as strontium titanium oxides (e.g., SrTiO₃) and yttrium oxides (e.g., Y₂O₃) have been grown on silicon substrates. More recently, epitaxial structures with closer lattice-matching have been grown, allowing for silicon substrate/epitaxial oxide/epitaxial silicon multi-layer structures. Grown epitaxial oxides with closer lattice-matching properties include oxides of rare earth metals and rare earth metal alloys such as cerium, yttrium, lanthanum, samarium, gadolinium, europium, and combinations thereof (e.g. cerium oxides (CeO₂) and lanthanum yttrium oxides (LaₓY₁₋ₓ)₂O₃).

### SUMMARY

Embodiments of the present invention provide a method for isolating a semiconductor device. The method comprises the step of epitaxially growing an insulating material on a crystalline substrate. The method further comprises the step of etching a recess into the insulating material, the recess extending less than a thickness of the insulating material. The method further comprises the step of epitaxially growing a semiconductor material within the recess of the insulating material, and forming the semiconductor device utilizing the epitaxial semiconductor material.

Other embodiments provide a semiconductor structure comprising a crystalline substrate, an epitaxial insulating layer grown on the crystalline substrate, the epitaxial insulating layer having a recess in a surface of the epitaxial insulating layer opposite the crystalline substrate, and an epitaxial semiconductor region grown within the recess of the epitaxial insulating layer.

### BRIEF DESCRIPTION OF THE SEVERAL VIEWS OF THE DRAWINGS

The following detailed description, given by way of example and not intended to limit the disclosure solely thereto, will best be appreciated in conjunction with the accompanying drawings, in which:

FIG. 1 depicts a semiconductor substrate upon which embodiments of the present invention may be fabricated.

FIG. 2 illustrates the epitaxial growth of an insulating layer grown on a substrate, in accordance with an embodiment of the present invention.

FIG. 3 depicts the deposition of an etch mask over an insulating layer to expose an area of the insulating layer where a semiconductor device region is desired, in accordance with an embodiment of the present invention.

FIG. 4 illustrates an insulating layer etched to form a recess within the insulating layer, the recess extending less than the entirety of the depth of the insulating layer, in accordance with an embodiment of the present invention.

FIG. 5 depicts the epitaxial growth of a semiconductor material within the recess of the insulating layer, in accordance with an embodiment of the present invention.

FIG. 6 illustrates the removal of a portion of semiconductor material formed above a top surface of an insulating layer and the removal of an etch mask, in accordance with an embodiment of the present invention.

FIG. 7 depicts a semiconductor device formed on semiconductor material grown with a recessed portion of an insulating layer, utilizing at least a portion of the semiconductor material as a channel region.

### DETAILED DESCRIPTION

Detailed embodiments of the claimed structures and methods are disclosed herein. The method steps described below do not form a complete process flow for manufacturing integrated circuits. The present embodiments can be practiced in conjunction with the integrated circuit fabrication techniques currently used in the art, and only so much of the commonly practiced process steps are included as are necessary for an understanding of the described embodiments. The figures represent cross-section portions of a semiconductor chip or a substrate during fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

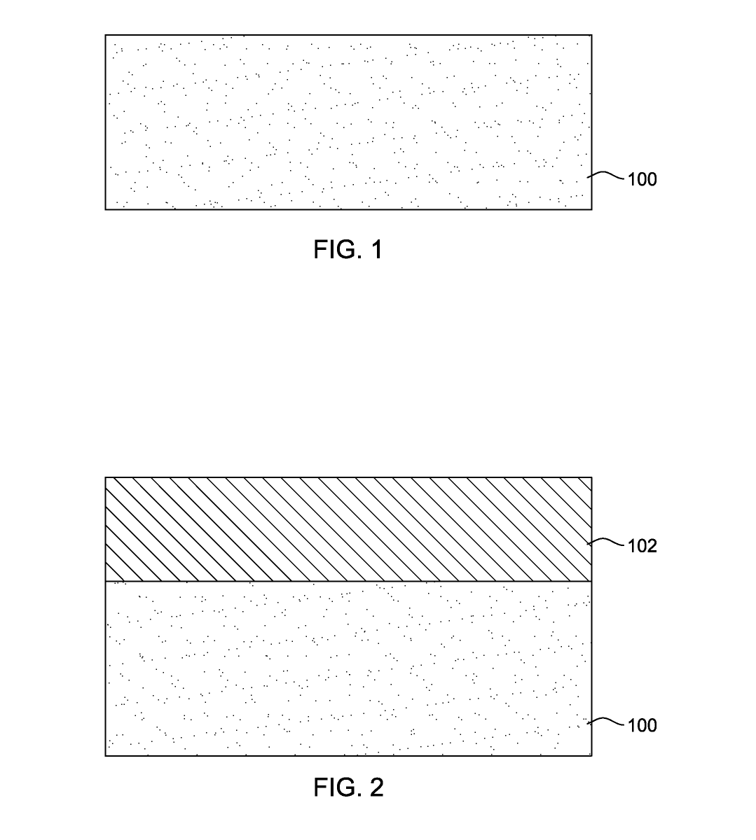

Sequential steps of an exemplary embodiment of a method for isolating semiconductor devices on a substrate are described below with respect to the schematic illustrations of FIGS. 1-7. Similar reference numerals denote similar features.

Referring first to FIG. 1, a semiconductor substrate 100 is depicted, upon which embodiments of the present invention may be fabricated. A person of skill in the art will recognize that substrate 100 can be composed of any crystalline material. In a preferred embodiment substrate 100 is composed of a silicon containing material such as Si, single crystal Si, SiGe, single crystal silicon germanium, or combinations and multi-layers thereof. Substrate 100 may also be composed of other semiconductor materials, such as germanium and compound semiconductor substrates, such as type III/V semiconductor substrates, e.g., GaAs.

FIG. 2 depicts the epitaxial growth of an insulating layer 102 grown on substrate 100. Insulating layer 102 may be composed of any dielectric material that may be grown epitaxially over substrate 100. In a preferred embodiment, insulating layer 102 is an oxide material, which tends to have higher band gaps than other insulating materials. Exemplary oxides include LaY oxides, Ce oxides, Y oxides, SmY oxides, CeY oxides, LaGd oxides, GdEu oxides, and SrTi oxides. In a preferred embodiment, insulating layer 102 is lattice matched to substrate 100, wherein a lattice constant of insulating layer 102 is substantially a multiple of a lattice constant of substrate 100. Epitaxial structures are typically grown from gaseous or liquid precursors, with a substrate acting as a seed crystal layer. The precursors react and/or decompose on the substrate surface to produce a crystalline deposit. Methods of growing insulating layer 102 include, in a non-exhaustive list, molecular beam epitaxy (MBE), vapor-phase epitaxy (VPE), liquid-phase epitaxy (LPE), laser ablation, and reactive vacuum evaporation. A thickness of insulating layer 102 can be any thickness achievable through epitaxial growth. An exemplary range includes a thickness between fifty (50) and two hundred (200) nanometers (nm). In a preferred embodiment, insulating layer can be between 100 and 150 nm.

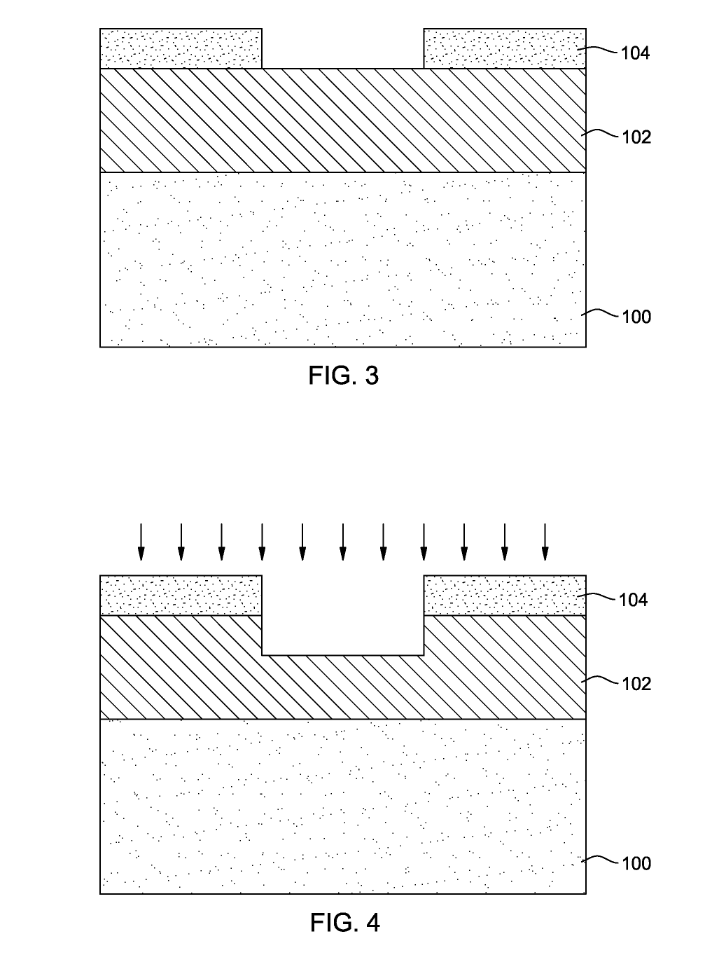

FIG. 3 depicts the deposition of etch mask 104 over insulating layer 102 to expose an area of insulating layer 102 where a semiconductor device region is desired. Etch mask 104 may comprise any etch resistant material. For example, a photoresist etch mask can be produced by applying a photoresist layer to the upper surface of insulating layer 102, exposing the photoresist layer to a pattern of radiation, and then developing the pattern into the photoresist layer utilizing a resist developer. The photoresist etch mask may be positioned so that one or more portions of insulating layer 102 are not protected by the photoresist etch mask.

Alternatively, a photoresist etch mask may be deposited over a hardmask and used to etch openings into the hardmask. The hardmask would serve as etch mask 104 for subsequent etch processes. A hardmask is preferable as it is not easily degraded during various etch processes. A hardmask may be made up of, by way of example, titanium nitride, silicon nitride, silicon dioxide, silicon carbide, silicon carbide nitride and/or combinations of the preceding.

As depicted in FIG. 4, insulating layer 102 is etched to form a recess within insulating layer 102, a depth of the recess extending less than the entirety of the depth of insulating layer 102. In a preferred embodiment, the remaining thickness of insulating layer 102, where insulating layer 102 has been recessed, is at least fifty (50) nm, to provide adequate isolation between a subsequent active layer and substrate 100. As the recess stops within insulating layer 102, without an etch stop layer that the etch process may be selective to, the depth of the recess is largely determined by a time of exposure to the etch process. The etch process is preferably an anisotropic reactive-ion etch (RIE). Other examples of anisotropic etching that can be used at this point of the present disclosure include ion beam etching, plasma etching or laser ablation. In an alternate embodiment, an isotropic etch, such as a wet chemical etch, may be used. An isotropic etch removes the material being etched at the same rate in each direction. Isotropic etch processes are contrary to anisotropic etch processes, which preferentially etch in one direction, such as with the reactive ion etch (RIE).

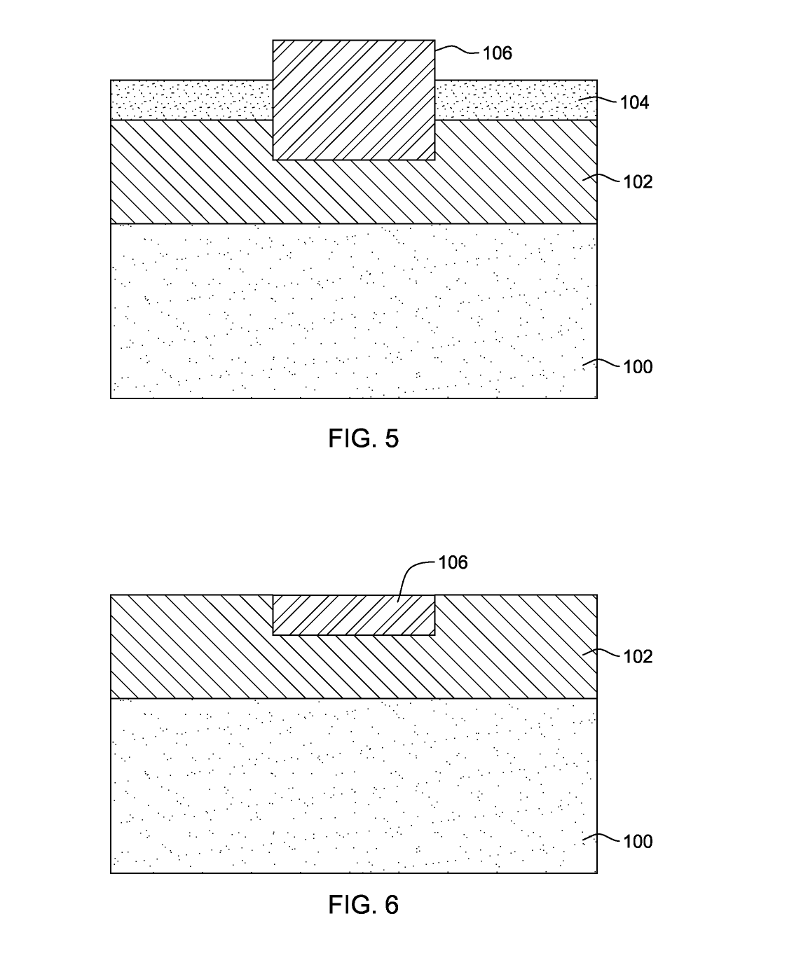

FIG. 5 illustrates the epitaxial growth of semiconductor material 106 within the recess of insulating layer 102. As with insulating layer 102, methods of growing semiconductor material 106 include, in a non-exhaustive list, molecular beam epitaxy (MBE), vapor-phase epitaxy (VPE), liquid-phase epitaxy (LPE), laser ablation, and reactive vacuum evaporation. In one embodiment, semiconductor material 106 is the same material as substrate 100. In other embodiments, semiconductor material 106 can be any semiconductor material capable of epitaxial growth on insulating layer 102. In a preferred embodiment, semiconductor material 106 is mono-crystalline and lattice matched to insulating layer 102.

FIG. 6 depicts the removal of a portion of semiconductor material 106 above a top surface of insulating layer 102 and the removal of etch mask 104. This may be performed by any planarization process. “Planarization” is a material removal process that employs at least mechanical forces, such as frictional media, to produce a planar surface. In one embodiment, the planarization process includes chemical mechanical polishing (CMP) or grinding. CMP is a material removal process using both chemical reactions and mechanical forces to remove material and planarize a surface.

The resulting structure is a semiconductor region (consisting of semiconductor material 106) within insulating layer 102. This semiconductor region may be used as a device region, wherein semiconductor devices may be built on and/or within the region. Growing semiconductor material 106 within the recess allows for a single crystal (mono-crystalline) channel, and hence high performance transistors, without subsequent masking and etching steps for isolation, which add complexity and can potentially add defects to the mono-crystalline structure. Contrary to silicon on insulator technology, this may be more accurately referred to as semiconductor in insulator technology. Additionally, without the use of an epitaxially grown isolation layer, semiconductor material 106 cannot be epitaxially grown, and the resulting polycrystalline film can significantly degrade device performance.

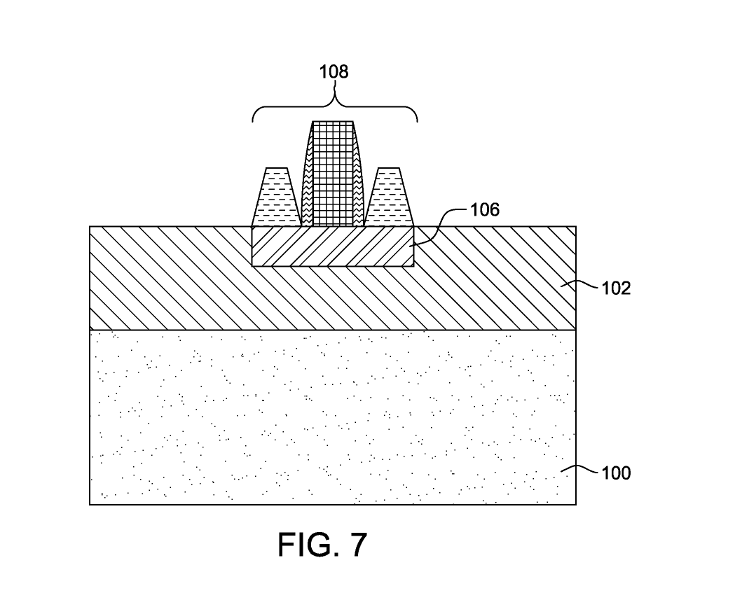

Referring now to FIG. 7, a semiconductor device (here depicted as field effect transistor 108) can be formed on semiconductor material 106, utilizing at least a portion of semiconductor material 106 as a (single crystal) channel region. By exploiting embodiments of the present invention, field effect transistor 108 is isolated from other semiconductor devices without the formation of trench isolation structures.

Other devices and components may be formed on substrate 100 and interconnected using one or more metallization layers.

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Having described preferred embodiments for isolating semiconductor devices on a substrate (which are intended to be illustrative and not limiting), it is noted that modifications and variations may be made by persons skilled in the art in light of the above teachings. It is therefore to be understood that changes may be made in the particular embodiments disclosed which are within the scope of the invention as outlined by the appended claims.

What is claimed is:

1. A method for isolating a semiconductor device, the method comprising the steps of:
epitaxially growing an insulating material on a crystalline substrate;
etching a recess into the insulating material;
epitaxially growing a semiconductor material within the recess of the insulating material; and
forming the semiconductor device utilizing the semiconductor material.

2. The method of claim 1, further comprising the step of, prior to forming the semiconductor device, removing a portion of the semiconductor material to produce a planar surface between a surface of the insulating material and a surface of the semiconductor material.

3. The method of claim 2, wherein the step of removing the portion of the semiconductor material comprises chemical-mechanical polishing.

4. The method of claim 1, wherein the epitaxially grown insulating material is an oxide.

5. The method of claim 1, wherein the epitaxially grown insulating material is mono-crystalline and wherein a lattice constant of the insulating material is substantially a multiple of a lattice constant of the crystalline substrate.

6. The method of claim 1, wherein the epitaxially grown semiconductor material is mono-crystalline and wherein a lattice constant of the semiconductor material is substantially a multiple of a lattice constant of the insulating material.

7. The method of claim 1, wherein the epitaxially grown semiconductor material is the same material as the crystalline substrate.

8. The method of claim 1, wherein the epitaxially grown semiconductor material is a different material than the crystalline substrate.

9. The method of claim 1, wherein the step of etching a recess into the insulating material comprises the steps of:
depositing a hardmask on a surface of the insulating material opposite the crystalline substrate, the hardmask exposing at least one area of the insulating material; and
performing a reactive-ion etch to remove a portion of the insulating material at the exposed at least one area of the insulating material.

10. The method of claim 1, wherein epitaxially growing the insulating material and the semiconductor material is accomplished by using a form of one of the following techniques: molecular beam epitaxy (MBE), vapor-phase epitaxy (VPE), liquid-phase epitaxy (LPE), laser ablation, and reactive vacuum evaporation.

11. A semiconductor structure comprising:
a crystalline substrate;
an epitaxial insulating layer grown on the crystalline substrate, the epitaxial insulating layer having a recess in a surface of the epitaxial insulating layer opposite the crystalline substrate; and
an epitaxial semiconductor region grown within the recess of the epitaxial insulating layer.

12. The semiconductor structure of claim 11, further comprising a semiconductor device formed on the epitaxial semiconductor region.

13. The semiconductor structure of claim 11, wherein the crystalline substrate is a silicon containing material.

14. The semiconductor structure of claim 11, wherein the crystalline substrate is mono-crystalline.

15. The semiconductor structure of claim 11, wherein the epitaxial insulating layer is an oxide.

16. The semiconductor structure of claim 15, wherein the epitaxial insulating layer is an oxide of one or more of yttrium, cerium, lanthanum, samarium, gadolinium, and europium.

17. The semiconductor structure of claim 11, wherein the epitaxial insulating layer is mono-crystalline.

18. The semiconductor structure of claim 11, wherein the epitaxial semiconductor region is mono-crystalline.

19. The semiconductor structure of claim 11, wherein the epitaxial insulating layer is lattice matched to the crystalline substrate, and wherein the epitaxial semiconductor region is lattice matched to the epitaxial insulating layer.

20. The semiconductor structure of claim 11, further comprising:
a second recess in the surface of the epitaxial insulating layer; and
a second epitaxial semiconductor region formed within the second recess, wherein the second epitaxial semiconductor region is isolated from the first epitaxial semiconductor region by a non-recessed portion of the epitaxial insulating layer.
